(19) United States
(12) Patent Application Publication
(10) Pub. No.: US 2021/0118879 A1
(43) Pub. Date: Apr. 22, 2021

(54) METHOD OF MAKING A CHARGE TRAP TFET SEMICONDUCTOR DEVICE FOR ADVANCED LOGIC OPERATIONS

(71) Applicant: Tokyo Electron Limited, Tokyo (JP)

(72) Inventors: Mark I. GARDNER, Cedar Creek, TX (US); H. Jim Fulford, Marianna, FL (US); Anton deVilliers, Clifton Park, NY (US)

(73) Assignee: Tokyo Electron Limited, Tokyo (JP)

(21) Appl. No.: 16/656,911

(22) Filed: Oct. 18, 2019

(51) Int. Cl. H01L 27/092; H01L 25/065; H01L 25/00; H01L 29/06; H01L 29/66; H01L 29/792

(52) U.S. Cl. CPC H01L 27/092; H01L 25/0657; H01L 29/792; H01L 29/0673; H01L 29/66833; H01L 25/50

(57) ABSTRACT

A charge trap tunnel field-effect transistor (TFET) includes multiple layers of dielectric material defining a charge trapping layer. A p-doped source/drain region and an n-doped source region are connected via a nano-channel, the nano-channel being formed between the multiple layers of dielectric, thus forming a charge trap TFET.

### BACKGROUND

### Technical Field

The present application relates to manufacturing of semiconductor devices. More particularly, it relates to manufacturing of three dimensional (3D) transistors, including charge trap tunnel field-effect transistors (TFETs) using multiple selective nano-sheets for fabrication in different device regions.

### Description of the Related Art

In the manufacture of a semiconductor device (especially on the microscopic scale), various fabrication processes are executed such as film-forming depositions, etch mask creation, patterning, material etching and removal, and doping treatments. These processes are performed repeatedly to form desired semiconductor device elements on a substrate. Historically, with microfabrication, transistors have been created in one plane, with wiring/metallization formed above the active device plane, and have thus been characterized as two-dimensional (2D) circuits or 2D fabrication. Scaling efforts have greatly increased the number of transistors per unit area in 2D circuits, yet scaling efforts are running into greater challenges as scaling enters single digit nanometer semiconductor device fabrication. Semiconductor device fabricators have expressed a desire for 3D semiconductor circuits in which transistors are stacked on top of each other.

3D integration, i.e. the vertical stacking of multiple devices, aims to overcome scaling limitations experienced in planar devices by increasing transistor density in volume rather than area. Although device stacking has been successfully demonstrated and implemented by the flash memory industry with the adoption of 3D NAND devices, application to logic designs is substantially more difficult. 3D integration for logic chips (e.g., CPU (central processing unit), GPU (graphics processing unit), FPGA (field programmable gate array), SoC (System on a chip)) is being pursued.

### SUMMARY

Techniques herein include 3D architectures and methods of making 3D transistors using multiple selective nano-sheets for fabrication in different device regions (i.e. N-type MOS (NMOS), P-type MOS (PMOS), and new device types). In particular, the techniques relate to a method of making a charge trap TFET (both stacked NMOS TFET and PMOS TFET) to enable transistor types on multiple transistor planes. The TFET device has very low sub-threshold slope (SS) and low power operation. By adding a fixed amount of controlled charge traps, improved custom device properties may be obtained for each transistor (i.e. robust transistor parameters, Vtcc, Idsat, Idoff). This allows for 3D integration since the transistor Vt may be altered by electrical programming to greatly expand logic options for 3D circuits.

Embodiments include charge trap TFETs on multiple 3D nano-planes using stacked nano-sheets to make a TFET charge trap transistor with a 3D device layout. The charge trap TFET may be used to set threshold devices of NMOS and PMOS to optimize logic designs. The TFET charge trap transistor may consist of a stack of multiple (e.g., one, two, or three) layers of dielectric to define the charge trapping layer in a nano-plane TFET.

The charge trap feature allows the Vt to be set to various values to modulate the Vt by process conditions of charge trapping. Additionally, the charge trap TFET can be electrically programmed and further re-programmed as needed to change the Vt to multiple values. This unique feature acts as a 3D switch. This feature may enable certain parts of the circuit to be modified for changing logic and circuit functions using the Vt to modulate the circuit (i.e., if the Vt of the charge trapped value is above the circuit Vt value, the transistor (charge trap TFET) will be turned off)). Additionally, the 3D charge trap TFET may also be utilized as a memory element in certain regions of the circuit.

A robust TFET with charge trapping is essential to enable the TFET to have optimum device properties (Idsat, Idoff, Vtcc). TFET devices with low power and SS are needed for 3D memory circuits with 3D circuit logic, which is also the case for many other circuit designs.

This application describes a method of making these devices on multiple nano-planes with different materials for effective circuit layout and design. Many other circuit logic blocks need the key elements discussed herein to become viable using nano-sheets and 3D device architecture.

Since the charge trap TFET can be electrically programmed to change the Vt, unique logic elements (e.g., static random-access memory (SRAM), inverters, transistors and other essential logic blocks in 3D) can be made but also altered to establish a key 3D logic circuit where the logic and memory elements may be re-programmed for the specific circuit application.

In one embodiment, a stack of a PMOS charge trap TFET and an NMOS charge trap TFET formed on a substrate, with particular separate control of the gate electrodes of the PMOS TFET and the NMOS TFET and also separate control logic connections for both source and drain region, is used as an inverter device.

The order of the different steps as described herein is presented for clarity sake. In general, these steps can be performed in any suitable order. Additionally, although each of the different features, techniques, configurations, etc., herein may be discussed in different places of this disclosure, it is intended that each of the concepts can be executed independently of each other or in combination with each other. Accordingly, the features of the present application can be embodied and viewed in many different ways.

This summary section does not specify every embodiment and/or novel aspect of the present application. Instead, this summary only provides a preliminary discussion of different embodiments and corresponding points of novelty over conventional techniques. Additional details and/or possible perspectives of the disclosed embodiments are described in the Detailed Description section and corresponding Figures of the present disclosure as further discussed below.

### BRIEF DESCRIPTION OF THE DRAWINGS

The application will be better understood in light of the description which is given in a non-limiting manner, accompanied by the attached drawings in which:

FIG. 1 shows a schematic of a cross section of a stack of two charge trap TFETs.

FIG. 2 shows a cross section of the stack of two charge trap TFETs of FIG. 1 along a direction perpendicular to the devices, showing nano-channels surrounded by a plurality of dielectric layers comprising a charge trapping layer.

FIG. 3 shows a table of dielectrics in a three dielectric layer stack for charge trapping.

FIG. 4 shows a table of dielectrics in a two dielectric layer stack for charge trapping.

FIG. 5 shows a table of dielectrics in a single dielectric layer stack for charge trapping.

FIG. 6 shows a schematic of a cross section of a charge trap TFET gate oxide region showing the channel and three adjacent dielectric regions.

FIG. 7 shows a schematic of a cross section of a stack of two charge trap TFETs

FIG. 8 shows a schematic of a cross section of a stack of two charge trap TFETs used as an inverter.

FIG. 9 shows a schematic of a cross section of a stack of two charge trap TFETs, with the metal gate deposited together during processing, used as an inverter.

FIGS. 10-21 show different steps in the fabrication of side-by-side stacks of TFET devices.

FIG. 22 shows a schematic of an array of charge trap TFETs.

### DETAILED DESCRIPTION OF THE PREFERRED EMBODIMENTS

Reference throughout this specification to “one embodiment” or “an embodiment” means that a particular feature, structure, material, or characteristic described in connection with the embodiment is included in at least one embodiment of the application, but do not denote that they are present in every embodiment. Thus, the appearances of the phrases “in one embodiment” or “in an embodiment” in various places throughout this specification are not necessarily referring to the same embodiment of the application. Furthermore, the particular features, structures, materials, or characteristics may be combined in any suitable manner in one or more embodiments.

Embodiments described herein include a stack of transistor substrate planes to make a multi-dimensional logic circuit on multiple transistor planes. Devices herein are embodied using nano-channels. In general, the term “nano-channel” means either a nano-wire or a nano-sheet shaped channel for a field effect transistor. A nano-wire is a relatively small elongated structure formed having a generally circular cross section or rounded cross section. Nano-wires are often formed from layers that are pattern etched to form a channel having a generally square cross-section, and then corners of this square cross-section structure are rounded, such as by etching, to form a cylindrical structure. A nano-sheet is similar to a nano-wire in that it has a relatively small cross section (less than a micron and typically less than 30 nanometers), but with a cross section that is rectangular. A given nano-sheet can include rounded corners.

To date, a complete effective solution has not been demonstrated using stacked nano-sheets to make a TFET charge trap transistor with a 3D device layout. Since the TFET transistor can have a controlled amount of trapped charge, the Vt, Idsat, Idoff and other key device properties may be controlled on selective regions/locations of a circuit or even at the individual transistor level.

A current complementary FET (CFET) stack is a 2 layer stack (non trapping stack), with layer 1 an oxide and layer 2 an HfO₂ layer. The charge trap TFET described here is compatible with the existing CFET.

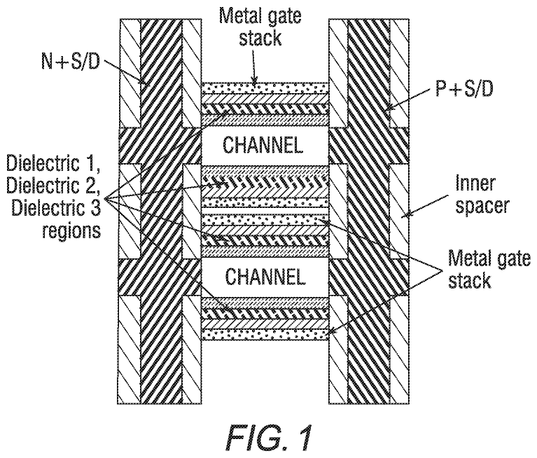

In one embodiment, the TFET charge trap transistor consists of a stack of 3 layers of dielectric to define the charge trapping layer in a nano-plane TFET. This is shown in FIG. 1. In particular, for the TFET device, one source/drain region is N-doped, while the source/drain region on the opposite side is P-doped. The configuration forms a tunneling FET device. The one source/drain region is connected to the other source/drain region via a nano-channel, thus forming a TFET. In FIG. 1, dielectric layer 1 (for example, oxide) is a tunneling dielectric layer; dielectric layer 2 (for example, a high k layer, e.g., HfO₂) is the charge trapping layer; and dielectric layer 3 (for example, oxide) is the charge retention layer. These layers may be formed using atomic layer deposition (ALD), but other methods may be used, including chemical vapor deposition (CVD).

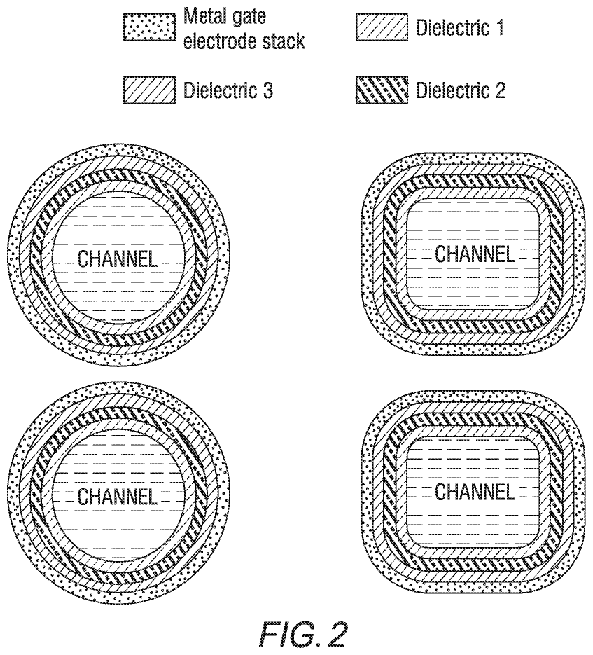

FIG. 2 shows a cross section of the nano-channel surrounded by the plurality of dielectric layers comprising the charge trapping layer. The cross section may be circular, square or rectangular.

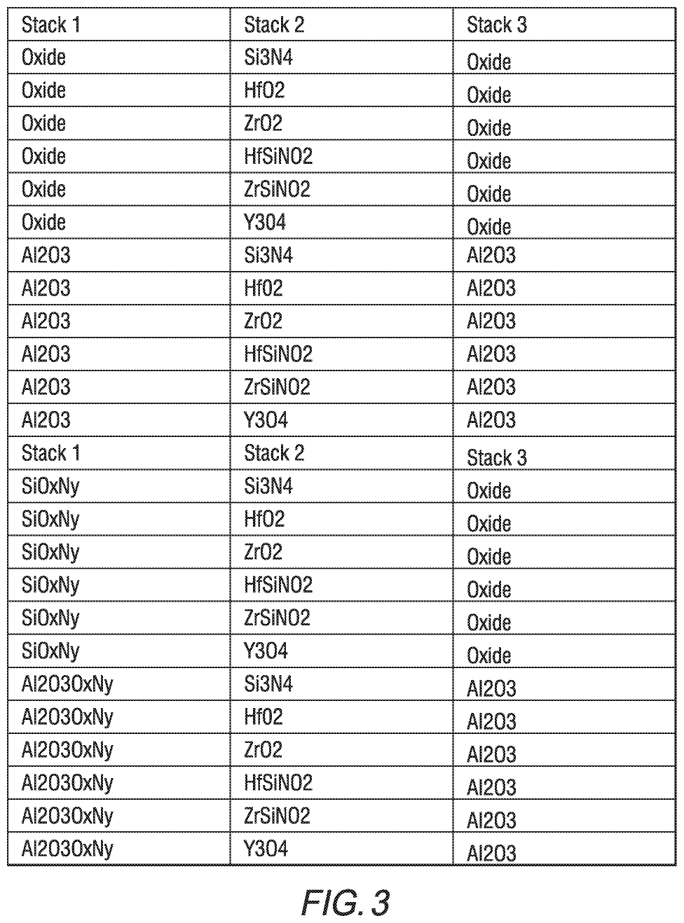

FIG. 3 shows examples of different materials that may be utilized to form the charge trap TFET transistor shown in FIG. 1. The material, thickness and properties for layer 1, layer 2, and layer 3 may be modified to tune and control the amount of charge trap in the TFET to the desired properties needed for the circuit application. Additionally, the charge trap TFET may be re-configured by biasing of the transistor to achieve different trapped charge states to optimize transistor performance in various regions of the circuit.

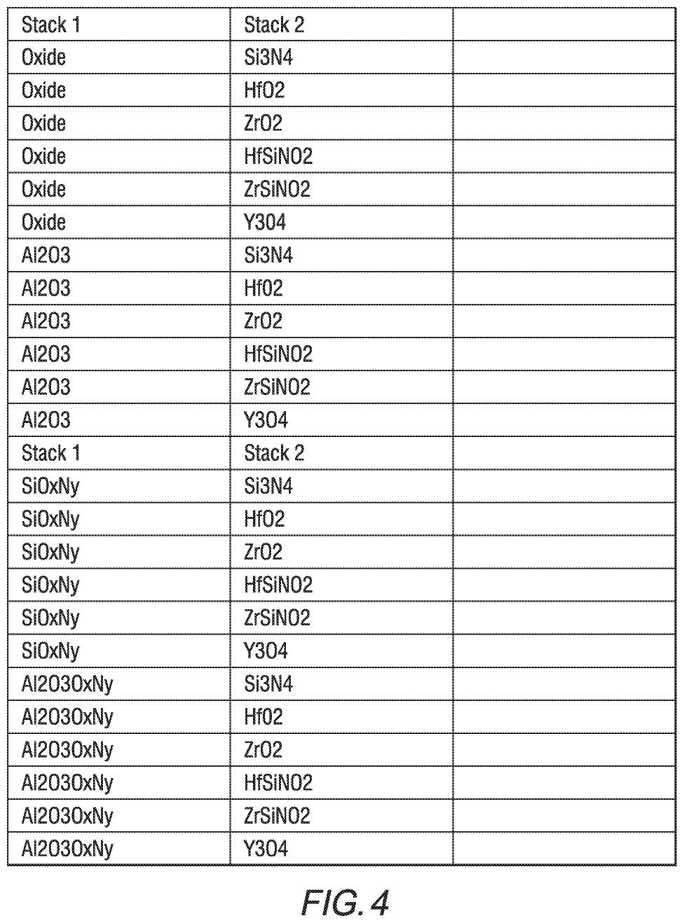

In another embodiment, the charge trapping layer comprises a stack of two layers of dielectric. FIG. 4 shows examples of different materials that may be utilized to form the charge trap TFET transistor. For the 2 layer stack system, the high-k material of dielectric layer 2 is deposited to form charge traps that may be contained with just 2 dielectric depositions.

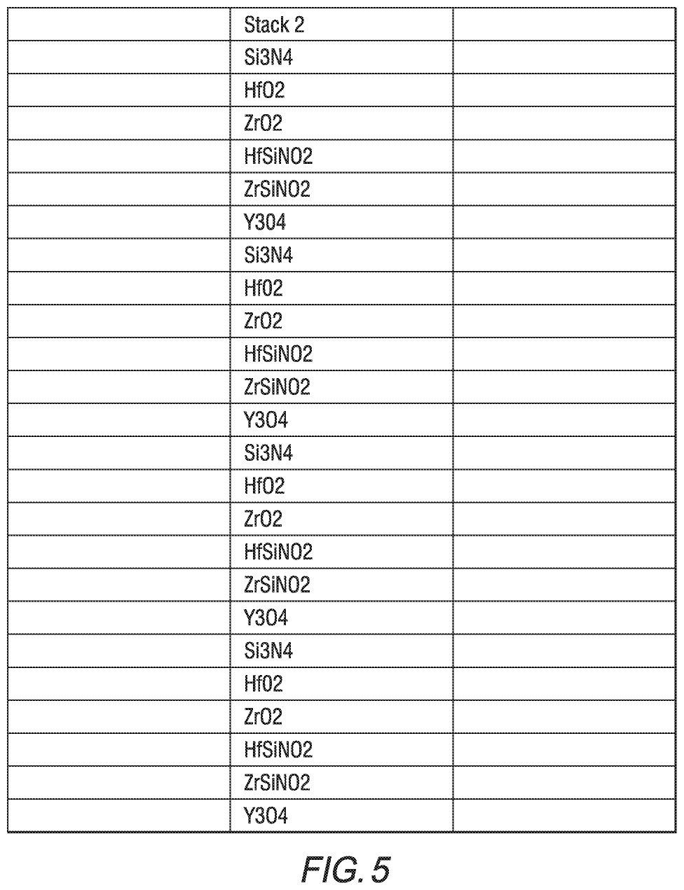

In still another embodiment, the charge trapping layer comprises one layer of dielectric. FIG. 5 shows examples of different materials that may be utilized to form the charge trap TFET transistor. For the 1 layer stack system, the high k material is deposited to form charge traps with just one dielectric deposition.

Both the 2 layer dielectric deposition and 1 layer dielectric deposition can result in a 3 layer system (i.e. oxide interface/high k/oxide) that is generated by in-situ processing. Another option is that a 2 layer or 1 layer system can remain a 2 layer or 1 layer system with the use of the right gate electrode and dielectric combinations. After each dielectric is formed, an in-situ anneal is also an option to set the optimum amount of charge traps.

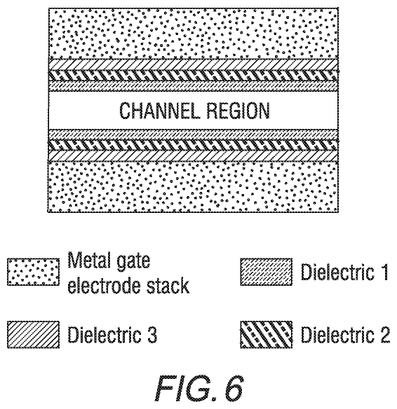

A typical 3 layer system is shown in FIG. 6, using HfO₂ as the second dielectric layer. In this example, the minimum 3 layer dielectric thickness is 0.9 nm, and the maximum 3 layer dielectric thickness is 3.5 nm. Also, since different high-k materials have a different k value, the physical thickness will change depending on which material is utilized.

Both the maximum and minimum thickness can be higher or lower depending on the circuit requirements (Vt, Idoff and Idsat). Also, since different high k materials have a different k value, the equivalent oxide thickness (EOT) is lower for HfO₂ at a given HfO₂ thickness relative to SiO₂. It is noted that in the method described here, the higher k region is the charge trap layer.

The EOT of a layer is given by:

EOT=thickness of high k layer (k of SiO₂/k of high k layer)

In one example, for an HfO₂ layer of thickness 1.5 nm=15 A, the EOT is EOT=1.5 nm (3.9/25)=0.234 nm=2.34 A oxide equivalent. That is, the thickness of HfO₂ at 15 A is equivalent to 2.34 A of oxide. By using higher k material, a charge trapping layer can be formulated with thicker physical thickness but small EOT.

Using the three stack dielectric deposition, a 3D stack of TFET charge trapping devices can be made in either NMOS or PMOS devices. The method described herein has the ability to alter the Vt of the charge trap device either by changing the process conditions or by selectively programming the TFET for the desired Vt window for optimum circuit performance.

In particular, the charge trap gate dielectric stack alone can alter the Vt of the device (material type, stack, and thickness). In addition, the metal gate material type work function alone can alter the Vt. The charge trap TFET may use just one type of metal but also has a feature of Vt adjustment by adding or subtracting charge traps in the charge trap dielectric stack (for example, more positive charge in channel for NMOS would raise the Vt of NMOS but decrease the Vt of PMOS, and more negative charge in channel for PMOS would increase the Vt of PMOS but decrease the Vtof NMOS).

It is noted that a combination of the above three can be used to alter the Vt.

Many different metal depositions are possible with both NMOS and PMOS to achieve the desired Vt values for the specific circuit application. Thus, the charge trap TFET allows a much more and flexible selection for NMOS and PMOS devices.

A feature of the present application is that one metal type is used for both NMOS and PMOS charge trap TFET devices, which greatly reduces the process complexity. Some common metals that may be used are Ti, Ta, TN, TaN, W, Ru, Pt, Co, NiSi, WSi, PtSi, and CoSi.

The range for the values of the altered Vt for NMOS TFET may be, for example, from 0.2V to 1.5V and for PMOS TFET from −0.2V to −1.5V (preferred range for low voltage (LV) logic circuits). However, the devices of the present application may cover higher voltage ranges for high voltage (HV) logic circuits. In general, an NMOS TFET device has a positive Vt value and a PMOS TFET has a negative Vt value. Any of the three Vt setting processes discussed above may establish a Vt value of 0.2V to 1.5V for NMOS and Vt value of −0.2V to −1.5V for PMOS.

In one embodiment of a three layer PMOS charge trap TFET, the sequence of the layers and their thicknesses is shown below. Since the Vt can be tuned for each transistor, a large selection of metal gate electrode materials is possible.

Dielectric 1: 0.3 nm to 1.0 nm, interfacial oxide layer

Dielectric 2: 0.3 nm to 10.0 nm, HfO₂, equivalent oxide thickness (EOT) range of 0.124 nm to 1.56 nm SiO2 equivalent for HfO₂.

Dielectric 3: 0.3 nm to 1.0 nm, oxide layer

TiN: 0.9 nm

TaN: 0.9 nm

TiON: 2.7 nm

TiC: 2.7 nm

In one embodiment of a three layer NMOS charge trap TFET, the sequence of the layers and their thicknesses is shown below.

Dielectric 1: 0.3 nm to 1.0 nm, interfacial oxide layer

Dielectric 2: 0.3 nm to 10.0 nm, HfO₂, equivalent oxide thickness (EOT) range of 0.124 nm to 1.56 nm SiO₂ equivalent for HfO₂.

Dielectric 3: 0.3 nm to 1.0 nm, oxide layer

TiC: 2.7 nm

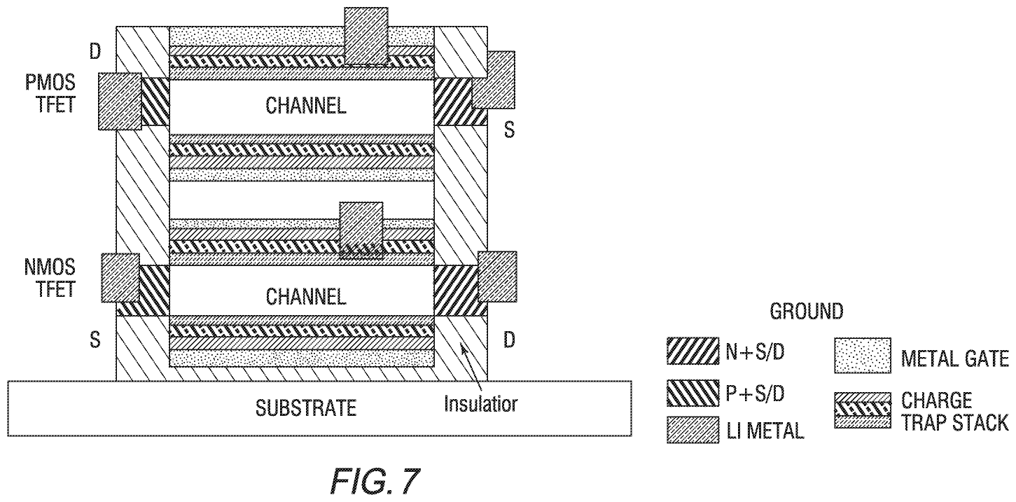

In another embodiment, the TFET charge trap transistor consists of a stack of a PMOS charge trap TFET and an NMOS charge trap TFET formed on a substrate. This is shown in FIG. 7. In particular, in the bottom NMOS charge trap TFET, a P-doped source region is connected to the N-doped drain region by a nano-channel, thus forming an NMOS TFET. In addition, dielectric layer 1 (for example, oxide) is a tunneling dielectric layer; dielectric layer 2 (for example, a high k layer, e.g., HfO₂) is the charge trapping layer; and dielectric layer 3 (for example, oxide) is the charge retention layer. These layers may be formed using ALD and define the charge trapping layer. The upper PMOS charge trap TFET has a similar configuration as the lower NMOS charge trap TFET.

The charge trap TFET device of FIG. 7 can have separate control of the gate electrode of the NMOS TFET and the gate electrode of the PMOS TFET, as well as separate logic control for both the source and drain regions of the two TFETs. As shown in FIG. 7, Li metal strap may be used to provide six connections to the gate electrodes of the two TFETs and the source/drain regions.

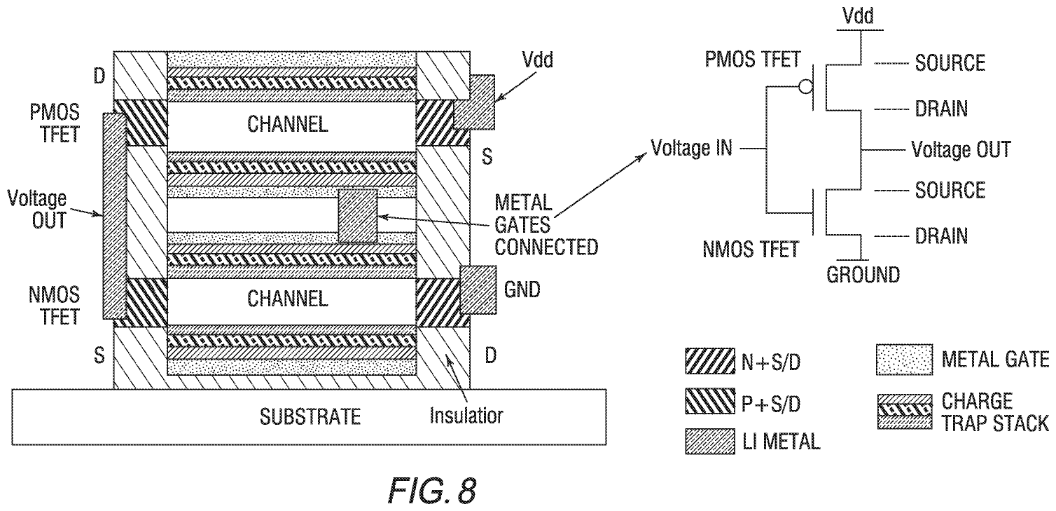

The charge trap TFET device of FIG. 7 can be used as an inverter, by appropriately configuring the connections of the source and drain regions and the gates, as seen in FIG. 8. In particular, by connecting with the Li strap the two gates, connecting the drain of the PMOS TFET with the source of the NMOS TFET to provide the Voltage Out, and applying the supply voltage Vdd to the source of the PMOS TFET, an inverter device may be implemented.

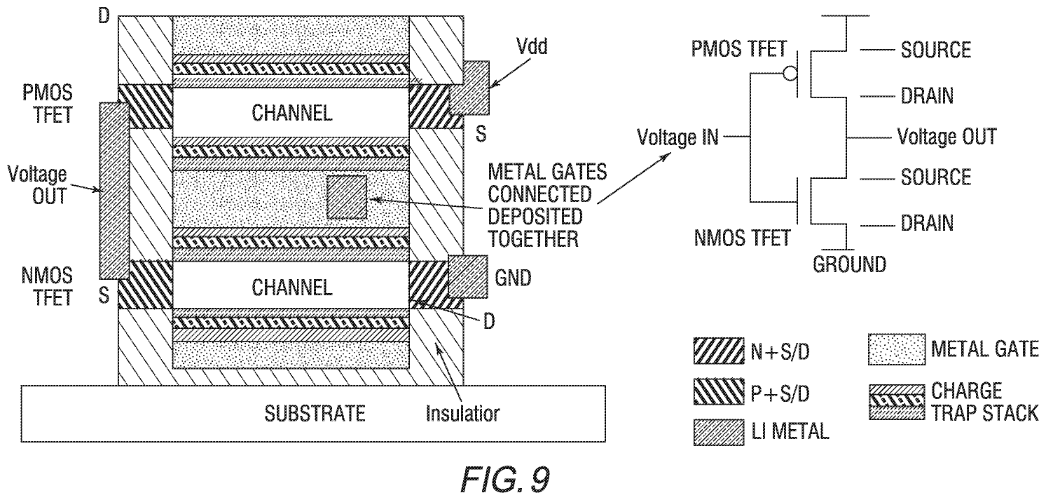

In a variation of the above embodiment, the charge trap TFET device of FIG. 8 can be used as an inverter by implementing connections of the source and drain regions and the gates differently than in the device of FIG. 8, as seen in FIG. 9. The difference from the connection in FIG. 8 is that the gates are formed via ALD with sufficient thickness so that they are in contact with each other, thus eliminating one metal connection.

A description of a method of fabricating the charge trap TFET of the present application is given below.

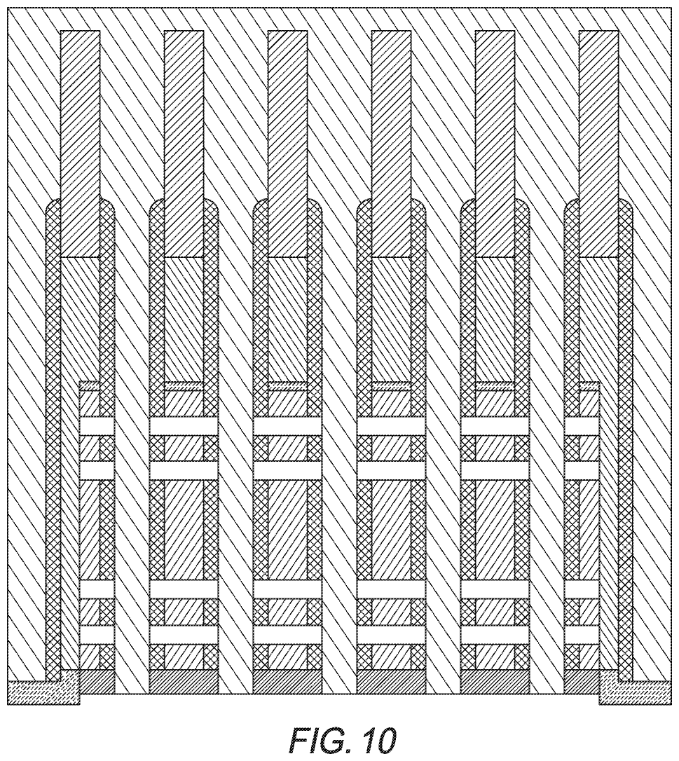

Referring now to FIG. 10, a nano-sheet stack is formed for gate-all-around stacked transistors. This can be, for example for a CFET 3D device. Starting material can be bulk silicon, bulk germanium, silicon on insulator (SOI), or other wafer or substrate. Multiple layers of material can first be formed as blanket depositions or epitaxial growth. In this example, nine layers of epitaxial growth are used. For example, layers of silicon, silicon germanium, and germanium in various molecular combinations can be grown, Si(65)Ge(35)/SiₓGe_{y}/Si/SiₓGe_{y}/Si/SiₓGe_{y}/Si/SiₓGe_{y}/Si, with typical ranges x from 0.6 to 0.8, and y from 0.4 to 0.2. Then, an etch mask is formed on top of the film stack. The film stack can be anisotropically etched to form nano-sheet stacks. Self-aligned double patterning or self-aligned quad patterning can be used to form an etch mask. Buried power rails can be formed. Additional microfabrication steps can include shallow trench isolation (STI) formation, creating dummy gates with poly silicon, selective SiGe release, depositing and etching low-k materials, and sacrificial spacer and inner spacer formation. FIG. 10 shows an example substrate segment after this processing. Also shown is an oxide fill between nano-sheet stacks and/or top tier encapsulation.

Continuing from this nano-sheet stack, trenches are opened at specific locations to form p-doped or n-doped source/drain regions at either horizontal or vertical locations.

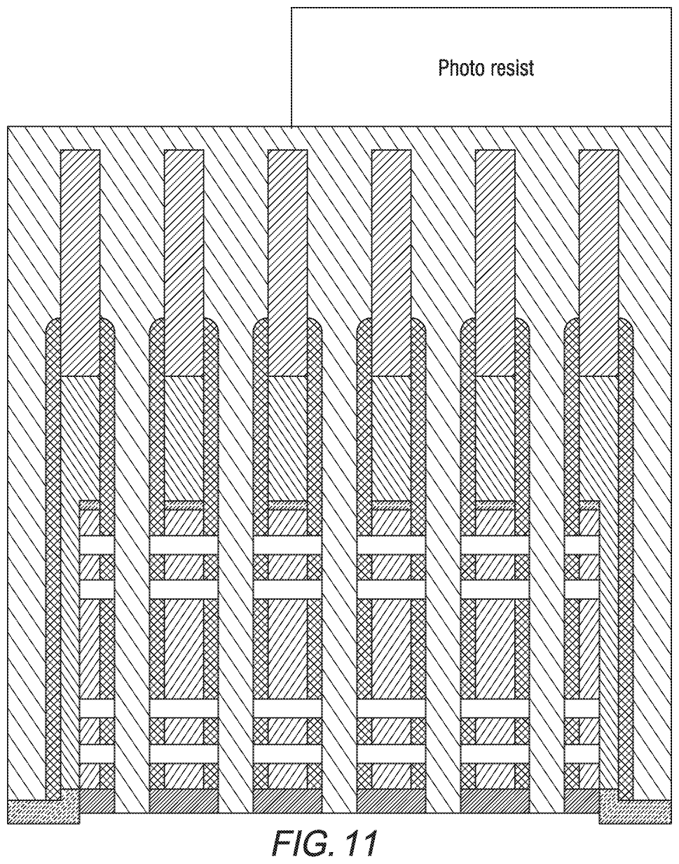

A photomask is formed at specific locations on the substrate to block or cover up NMOS regions, as illustrated in FIG. 11.

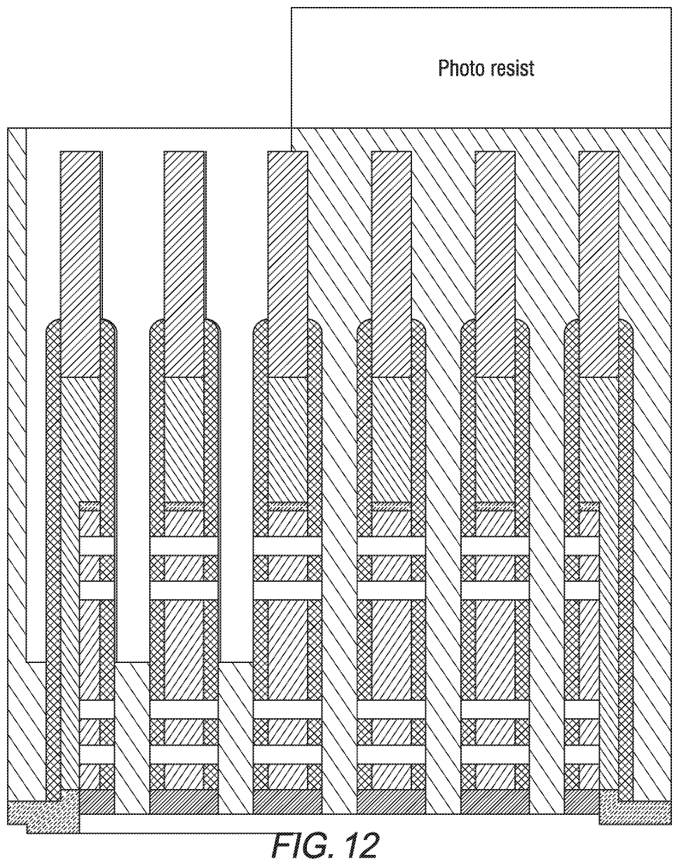

With NMOS regions blocked, the oxide fill (or other fill material) can be removed from in between uncovered nano-sheet stacks. Note that the oxide fill can be removed at one or more planes of channels. Note that in this example, with two planes of transistor, the oxide fill is first removed down to a break between the upper transistor plane and the lower transistor plane. An example is shown in FIG. 12. Then, silicon nitride spacers can be formed on sidewalls of the nano-sheet stacks. This can be accomplished by conformal deposition followed by a spacer open etch (directional etch). Thus, the top P+ future source/drain region is covered up to prevent growth in a subsequent step.

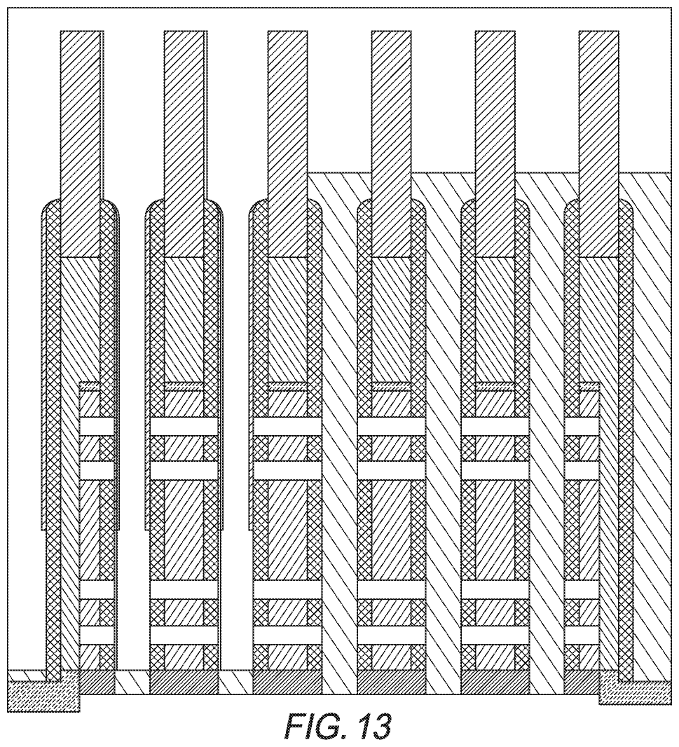

Another anisotropic etch is executed to remove oxide fill from the lower transistor plane, thereby uncovering silicon of the nano-sheet. The photomask can then be removed. FIG. 13 shows an example result.

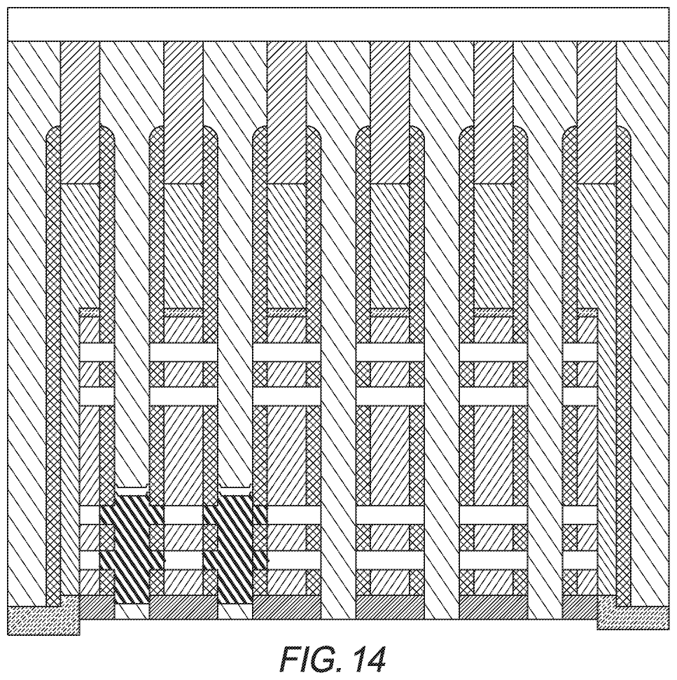

P-doped SiGe or other material can then be grown in the lower plane source/drain region. After completing epitaxial growth, the substrate can be filled with oxide. Any overburden can be removed using chemical-mechanical polishing (CMP) or other planarization techniques. FIG. 14 illustrates an example result of a cross-section of a substrate segment.

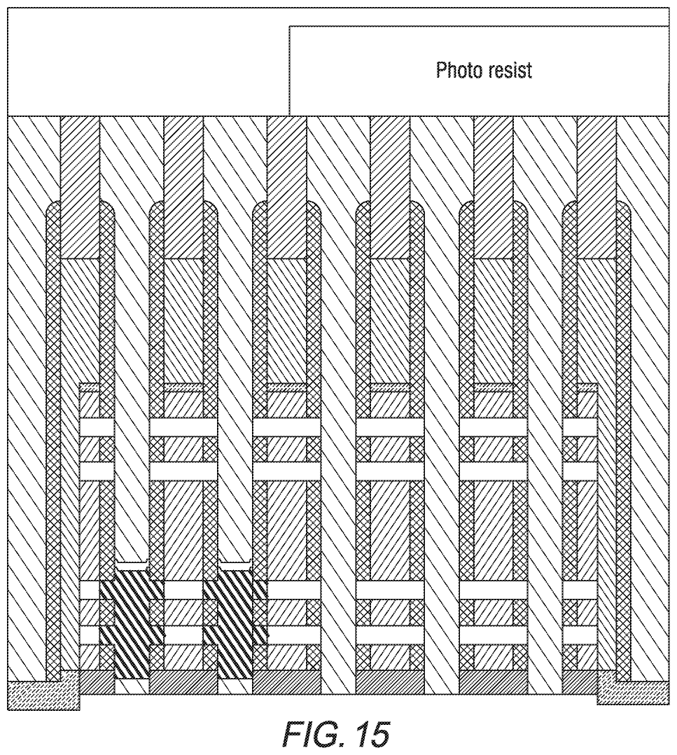

Next, a photomask is formed again to again cover the NMOS region in this example. FIG. 15 illustrates an example result.

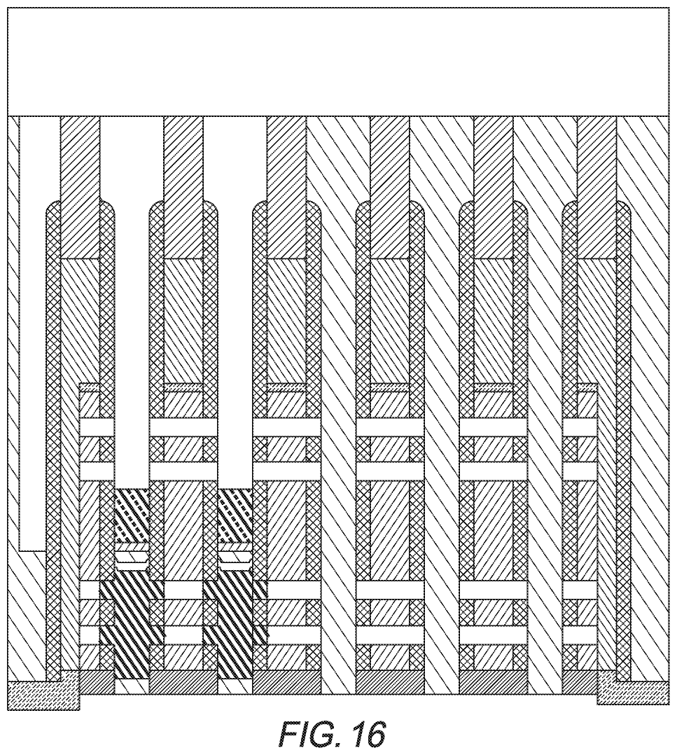

Oxide fill is removed to uncover the upper transistor plane. Note that oxide fill can be removed down to the source/drain region of the lower transistor plane, with a spacer then added. Or, oxide fill removal can stop before the source/drain region of the lower transistor plane, to leave a spacer between the upper and lower source drain regions. After the oxide recess, the silicon nitride sidewalls covering the silicon nano-sheets can be removed. The photomask can also be removed. An example result is illustrated in FIG. 16.

Local interconnects can also be formed at this point while the bottom source/drain region is uncovered. This can include various deposition, masking, selective removal, and selective deposition steps, such as to form ruthenium contacts or other desired metal.

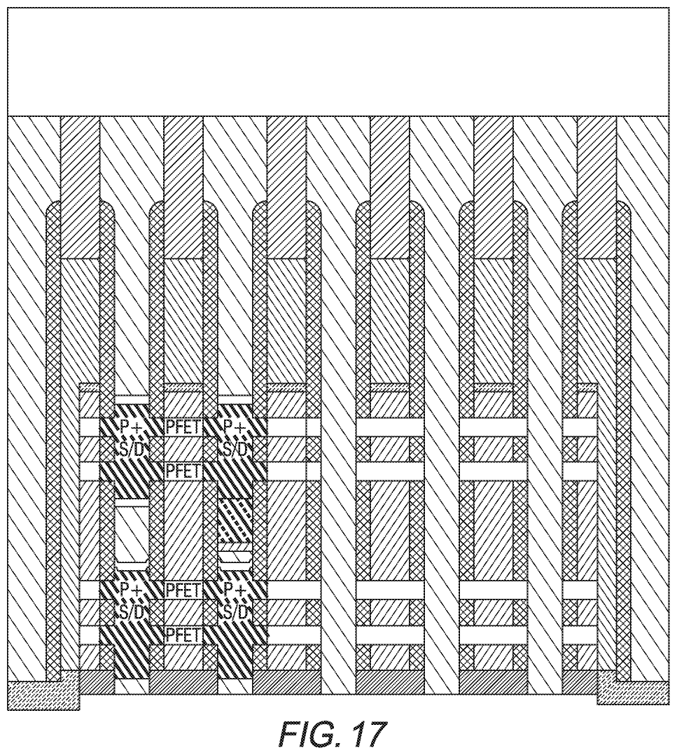

P-doped source/drain regions can then be grown in uncovered portions of the upper transistor plane. The substrate can then be filled again with oxide and planarized. An example result is illustrated in FIG. 17.

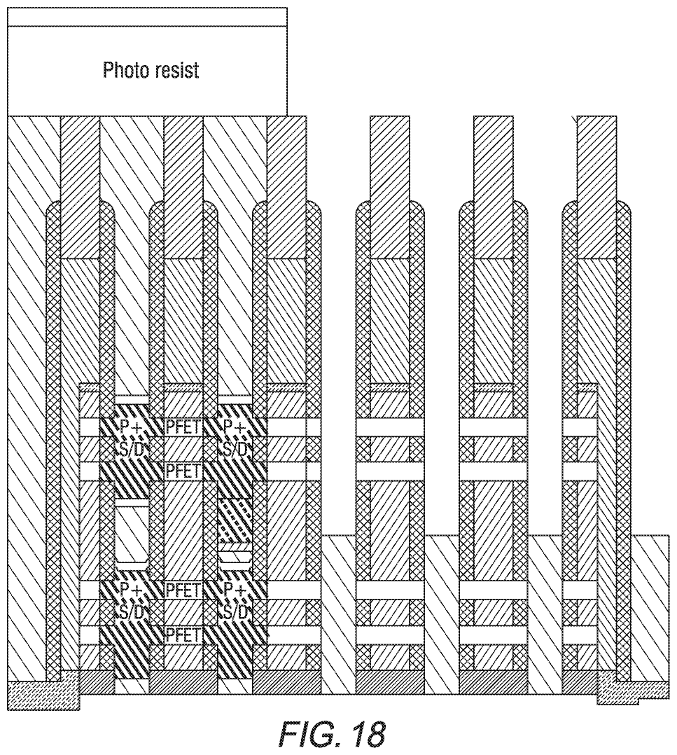

Processing can next continue with N-doped source/drain formation. A third photomask is added to cover P-doped source drain regions on the substrate. The oxide fill is recessed sufficiently to uncover the upper transistor plane while the lower transistor plane remains covered. An example result is illustrated in FIG. 18.

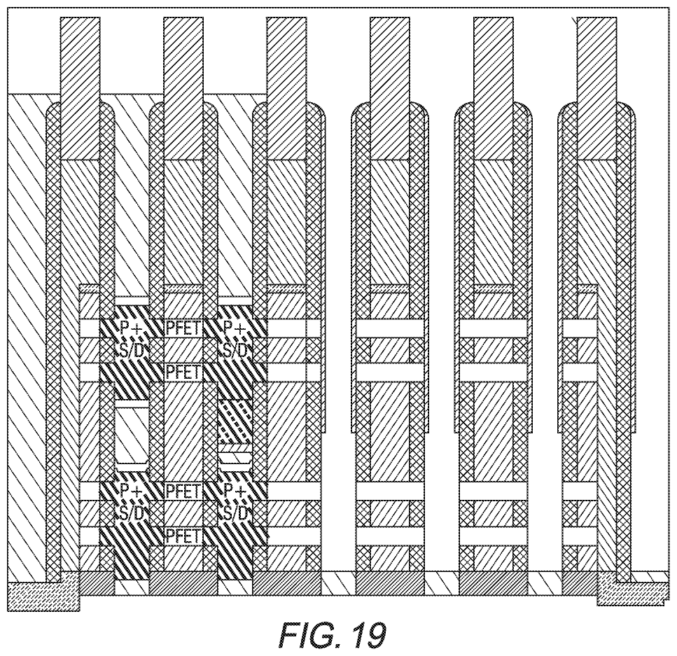

With upper silicon uncovered in the NMOS regions, a silicon nitride spacer can be added to cover silicon sidewalls. Then, the remaining oxide fill can be removed so that silicon from the nano-sheets in the lower transistor plane is uncovered. The third photomask can also be removed. An example result is illustrated in FIG. 19.

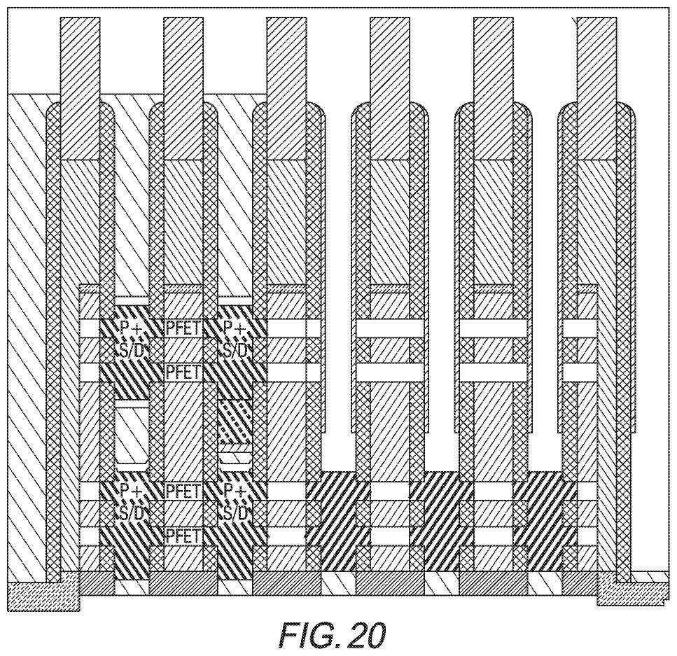

N-doped material can then be grown in the lower plane source/drain region. After completing epitaxial growth, the substrate can be filled with oxide. Any overburden can be removed using CMP or other planarization techniques. FIG. 20 illustrates an example result of a cross-section of a substrate segment.

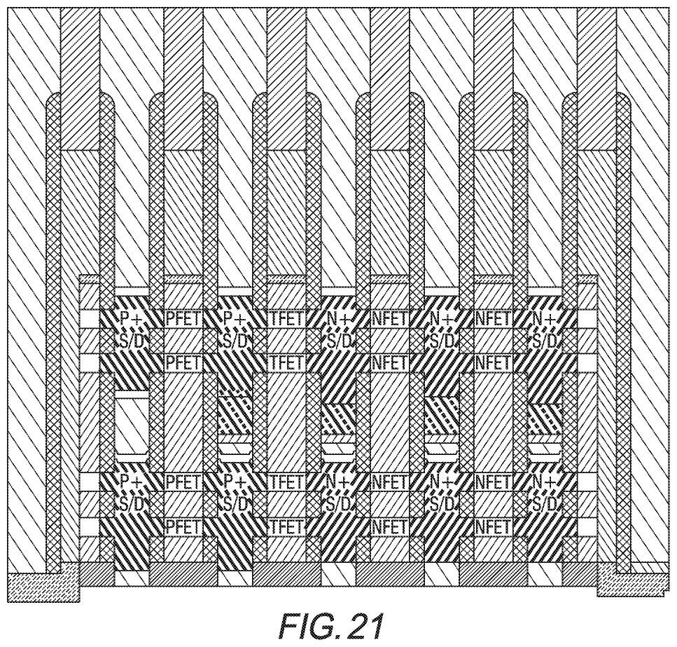

Similar processing as described for the upper P-doped source/drain region may be used for the upper N-doped source drain region. Oxide fill may be added to the trenches. An example result is illustrated in FIG. 21.

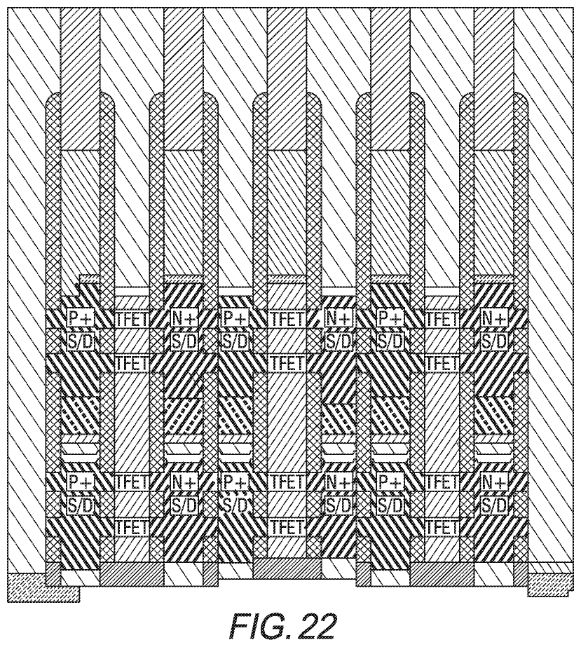

FIG. 22 shows an array of charge trap TFETs formed by the above method.

From this point, additional processing can be continued. For example, local interconnect steps can be completed as well as further wiring. Dummy poly gate material can be removed. Replacement metal gate for all transistors can be completed. This can include removing oxide, SiGe channel release, silicon etch trim, depositing interfacial SiO, depositing high-k material, depositing any of TIN, TaN, TiAl, or other desired work function metals. Replacement metal gate for PMOS device can include depositing organic planarization layer and recessing selected portions of the planarization layer, and removing TiAL.

Note that N-doped and P-doped source/drain regions can be interchanged at any level (vertical level) by changing the masking epi growth. Moreover, N-doped and P-doped source/drain regions can be interchanged at any horizontal coordinate location on the substrate. In this way, an array of charge trap TFTs can be implemented (for example, the configuration shown in FIG. 21 (extending in one dimension) extending in two dimensions). In other embodiments, different types of materials—and different doping levels—can be executed for S/D epi on different transistor planes.

Accordingly, side-by-side TFETs can be created with any number of FETs as needed for circuit elements. Symmetrical source/drain CMOS devices can be integrated with asymmetrical S/D TFET CMOS within a same process. Techniques herein enable flexible positioning of NMOS and PMOS devices to be integrated more efficiently for circuit design layout by having separate stacks for NMOS and PMOS devices in close proximity to each other. Methods herein provide flexibility to fabricate one nano-plane to more than ten nano-planes depending on circuit requirements or design objectives.

Advantages of the charge trap TFET described herein include: 1) by optimization of a precisely controlled charge trap population, a stable transistor with predicable transistor properties can be achieved (i.e. Ids vs Vt, Idoff vs Idsat); 2) lower SS and better performance with charge trap TFET devices (drive current is available per area of chip layout); 3) multiple and stable Vt values for low voltage; 4) new transistor architectures will enable N=1 to N≥10 substrate planes of transistors depending on circuit requirements: 5) the charge trap TFET of the present application may be co-integrated with existing CFET with a few extra process steps. The new charge trapping tunneling transistor will be needed for future scaling for low power and channel length scaling.

Various techniques have been described as multiple discrete operations to assist in understanding the various embodiments. The order of description should not be construed as to imply that these operations are necessarily order dependent. Indeed, these operations need not be performed in the order of presentation. Operations described may be performed in a different order than the described embodiment. Various additional operations may be performed and/or described operations may be omitted in additional embodiments.

“Substrate” or “target substrate” as used herein generically refers to an object being processed in accordance with the present application. The substrate may include any material portion or structure of a device, particularly a semiconductor or other electronics device, and may, for example, be a base substrate structure, such as a semiconductor wafer, reticle, or a layer on or overlying a base substrate structure such as a thin film. Thus, substrate is not limited to any particular base structure, underlying layer or overlying layer, patterned or un-patterned, but rather, is contemplated to include any such layer or base structure, and any combination of layers and/or base structures. The description may reference particular types of substrates, but this is for illustrative purposes only.

Those skilled in the art will also understand that there can be many variations made to the operations of the techniques explained above while still achieving the same objectives. Such variations are intended to be covered by the scope of this disclosure. As such, the foregoing descriptions of the embodiments are not intended to be limiting. Rather, any limitations to the embodiments are presented in the following claims.

1: A semiconductor device comprising:
a stack of tunneling field-effect transistors (TFETs) formed on a substrate, the stack extending perpendicular to a surface of the substrate, each TFET in the stack of TFETs including one nano-channel that connects one source/drain region on a first side of each TFET with another source/drain region on an opposite side of each TFET, wherein at least one dielectric layer is formed around the nano-channel, the at least one dielectric layer forming a charge trapping layer.

2: The semiconductor device according to claim 1, wherein
the at least one dielectric layer comprises a first oxide layer formed around the nano-channel, a high dielectric constant (k), dielectric layer formed around the first oxide layer, and a second oxide layer formed around the high k, dielectric layer.

3: The semiconductor device according to claim 1, wherein
the at least one dielectric layer comprises a first oxide layer formed around the nano-channel, and a high dielectric constant (k), dielectric layer formed around the first oxide layer.

4: The semiconductor device according to claim 1, wherein
the at least one dielectric layer comprises a high dielectric constant (k), dielectric layer formed around the nano-channel.

5: The semiconductor device according to claim 1, further comprising
a stack of metal gate electrodes formed between two adjacent TFETs in a direction normal to the surface of the substrate, the stack of metal gate electrodes connecting the one source/drain region of the TFET with the another source/drain region on the opposite side of the TFET.

6: The semiconductor device according to claim 5, wherein
the stack of metal gate electrodes includes layers of TiN, TaN, TiON and TiC.

7: The semiconductor device according to claim 1, wherein
the nano-channel comprises Si or SiGe.

8: The semiconductor device according to claim 2, wherein
the thickness of the at least one dielectric layer has a minimum value of 0.9 nm and a maximum value of 3.5 nm.

9: The semiconductor device according to claim 2, wherein
the high k, dielectric layer is HfO₂.

10: The semiconductor device according to claim 3, wherein
the high k, dielectric layer is HfO₂.

11: The semiconductor device according to claim 4, wherein
the high k, dielectric layer is HfO₂.

12: A semiconductor charge trap tunneling field-effect transistor (TFET) device comprising:
an n-type metal-oxide-semiconductor TFET (NMOS TFET) device formed on a substrate, the NMOS TFET device including one nano-channel that connects source/drain regions of the NMOS TFET device, wherein at least one dielectric layer is formed around the nano-channel, the at least one dielectric layer forming a charge trapping layer; and
a p-type metal-oxide-semiconductor TFET (PMOS TFET) device formed on the substrate and positioned directly above the NMOS TFET device with at least one spacer separating the NMOS TFET device from the PMOS TFET device, the PMOS TFET device including one nano-channel that connects source/drain regions of the PMOS TFET device, wherein at least one dielectric layer is formed around the nano-channel, the at least one dielectric layer forming a charge trapping layer, wherein
the drain region of the PMOS TFET is connected to the source region of the NMOS TFET, and metal connections are provided separately for the source and drain regions of the NMOS TFET and the PMOS TFET, as well as, for the gate electrodes of the NMOS TFET and the PMOS TFET.

13: The semiconductor device according to claim 12, wherein
gate electrodes of the NMOS TFET and the PMOS TFET are connected via a metal strap, the drain of the PMOS TFET is connected with the source of the NMOS TFET to provide an output voltage, and the source of the PMOS TFET is connected to a positive supply voltage Vdd, thus constituting an inverter device.

14: The semiconductor device according to claim 12, wherein
the gate electrodes of the NMOS TFET and the PMOS TFET are connected without a metal strap, the drain of the PMOS TFET is connected with the source of the NMOS TFET to provide an output voltage, and the source of the PMOS TFET is connected to a positive supply voltage Vdd, thus constituting an inverter device.

15: The semiconductor device according to claim 12, wherein
the at least one dielectric layer comprises a high dielectric constant (k), dielectric layer formed around the nano-channel.

16: A semiconductor device comprising:
a first FET (field-effect transistor) device formed on a substrate, the first FET device including at least one nano-channel that connects source/drain regions of the first FET device;
a second FET device formed on the substrate adjacent to the first FET device, the second FET device including at least one nano-channel that connects source/drain regions of the second FET device, wherein one source/drain region of the second FET device is shared with one source/drain region of the first FET device;
a third FET device formed on the substrate adjacent to the second FET device the third FET device including at least one nano-channel that connects source/drain regions of the third FET device, wherein one source/drain region of the third FET device is shared with one source/drain region of the second FET device, wherein
the semiconductor device is doped so that the first FET forms a p-channel FET, the second FET forms a tunneling FET, and the third FET forms an n-channel FET, and
at least one charge trapping layer of dielectric is formed around the at least one nano-channel in the first FET, the second FET and the third FET.

17: A semiconductor charge trap tunneling field-effect transistor (TFET) device comprising:
an p-type metal-oxide-semiconductor TFET (PMOS TFET) device formed on a substrate, the PMOS TFET device including one nano-channel that connects source/drain regions of the PMOS TFET device, wherein at least one dielectric layer is formed around the nano-channel, the at least one dielectric layer forming a charge trapping layer; and
an n-type metal-oxide-semiconductor TFET (NMOS TFET) device formed on the substrate and positioned directly above the PMOS TFET device with at least one spacer separating the NMOS TFET device from the PMOS TFET device, the NMOS TFET device including one nano-channel that connects source/drain regions of the NMOS TFET device, wherein at least one dielectric layer is formed around the nano-channel, the at least one dielectric layer forming a charge trapping layer, and wherein
the drain region of the NMOS TFET is connected to the source region of the PMOS TFET, and metal connections are provided separately for the source and drain regions of the PMOS TFET and the NMOS TFET, as well as, for the gate electrodes of the PMOS TFET and the NMOS TFET.

18: The semiconductor device according to claim 17, wherein
gate electrodes of the PMOS TFET and the NMOS TFET are connected via a metal strap, the drain of the NMOS TFET is connected with the source of the PMOS TFET to provide an output voltage, and the source of the NMOS TFET is connected to a positive supply voltage Vdd, thus constituting an inverter device.

19: The semiconductor device according to claim 17, wherein
the gate electrodes of the PMOS TFET and the NMOS TFET are connected without a metal strap, the drain of the NMOS TFET is connected with the source of the PMOS TFET to provide an output voltage, and the source of the NMOS TFET is connected to a positive supply voltage Vdd, thus constituting an inverter device.

20: The semiconductor device according to claim 17, wherein
the at least one dielectric layer comprises a high dielectric constant (k), dielectric layer formed around the nano-channel.
